(19) United States
(12) Patent Application Publication
(10) Pub. No.: US 2005/0244989 A1
(43) Pub. Date: Nov. 3, 2005

(54) Ion implantation apparatus and method

(76) Inventors: Takeshi Shibata, Yokohama-shi (JP); Kazuhiko Tonari, Susono-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/110,814

(22) Filed: Apr. 21, 2005

(30) Foreign Application Priority Data
Apr. 23, 2004 (JP) 2004-128057

(51) Int. Cl. H01L 21/00; H01L 21/84; H01L 21/66

(52) U.S. Cl. 438/5; 438/514; 438/510; 438/14

(57) ABSTRACT

An ion implantation apparatus includes an ion emission unit configured to emit ions to a plurality of regions of at least one substrate under different conditions. A substrate holding unit is configured to hold the substrate and change a position of the at least one substrate relative to the ions emitted from the ion emission unit. A computation unit is configured to prepare a correcting process condition for each of the regions based on correction information beforehand input for each of the regions. The correcting process condition is acquired by correcting a standard process condition used for ion emission. A controller controls the ion emission unit and the substrate holding unit to emit the ions to each of the regions under the correcting process condition.

### CROSS-REFERENCE TO RELATED APPLICATIONS

This application is based upon and claims the benefit of priority from prior Japanese Patent Application No. 2004-128057, filed Apr. 23, 2004, the entire contents of which are incorporated herein by reference.

### BACKGROUND OF THE INVENTION

1. Field of the Invention

The present invention relates to an ion implantation apparatus and method.

2. Description of the Related Art

When manufacturing semiconductor devices (chips), in general, a plurality of semiconductor devices are simultaneously formed on a single or a plurality of semiconductor substrates through common processes. Since semiconductor devices are required to have the same product characteristics (e.g., the same electrical characteristics), they are generally produced by performing each process on all element regions of a semiconductor substrate under the same conditions.

On the other hand, in the ion implantation apparatus disclosed in, for example, Jpn. Pat. Appln. KOKAI Publication No. 2000-3881, variations in characteristics between the regions of a semiconductor substrate are suppressed by implanting ions into the regions under the same conditions. However, variations caused in the other processes remain. In this case, the conditions, such as the amount of implanted ions and acceleration energy of the ions, are identical between the regions of the semiconductor substrate, although processes are performed in units of regions.

### BRIEF SUMMARY OF THE INVENTION

According to a first aspect of the present invention, there is provided an ion implantation apparatus comprising: an ion emission unit configured to emit ions to a plurality of regions of at least one substrate under different conditions; a substrate holding unit configured to hold the substrate and change a position of the at least one substrate relative to the ions emitted from the ion emission unit; a computation unit configured to prepare a correcting process condition for each of the regions based on correction information beforehand input for each of the regions, the correcting process condition being acquired by correcting a standard process condition used for ion emission; and a controller which controls the ion emission unit and the substrate holding unit to emit the ions to each of the regions under the correcting process condition.

According to a second aspect of the present invention, there is provided an ion implantation method for use in an ion implantation apparatus capable of emitting ions to a plurality of regions of at least one substrate under different conditions, comprising: preparing a correcting process condition for each of the regions based on correction information beforehand input for each of the regions, the correcting process condition being acquired by correcting a standard process condition used for ion emission; and emitting the ions to each of the regions under the correcting process condition.

### BRIEF DESCRIPTION OF THE SEVERAL VIEWS OF THE DRAWING

FIG. 1 is a schematic block diagram illustrating an essential part of an ion implantation apparatus according to a first embodiment of the invention;

FIGS. 2A, 2B, 2C, 2D, 3A, 3B and 4 are views useful in explaining preparation of correcting process conditions;

FIG. 5 is a graph illustrating, as examples, the transistor threshold voltages of semiconductor devices corresponding to the regions of semiconductor substrates;

FIG. 6 is a graph illustrating, as an example, the change ratio of the threshold voltage to the amount of implanted ions;

FIG. 7 is a view illustrating correction coefficient examples applied to a standard process condition; and

FIG. 8 is a graph illustrating variation examples in threshold voltage during standard implantation and correcting implantation.

### DETAILED DESCRIPTION OF THE INVENTION

As previously stated, it is desirable that the finished product characteristics of semiconductor devices formed in the respective regions of a semiconductor substrate be uniform. If variations in the characteristics of finished semiconductor devices exceed an allowable range, these semiconductor devices are considered defective and are therefore eliminated, which leads to increases in production cost.

At present, except for the ion implantation apparatus as disclosed in Jpn. Pat. Appln. KOKAI Publication No. 2000-3881, and exposure apparatuses, semiconductor-manufacturing apparatuses generally process a single or a plurality of semiconductor substrates under the same conditions. Ideally, if the respective-regions of the semiconductor substrate(s) are subjected to the same process, the same results will be acquired in the regions. Actually, however, variations in process result occur in the regions. Such variations remain as variations in characteristics between finished products unless they are offset by variation-offsetting factors in a later process, which reduces the yield of products.

The ion implantation apparatus as disclosed in Jpn. Pat. Appln. KOKAI Publication No. 2000-3881 and exposure apparatuses can process the respective regions of a semiconductor substrate under different conditions. However, at present, only at a trial manufacturing stage, the respective regions of a semiconductor substrate are processed under different conditions in order to research various conditions and characteristics, etc. Accordingly, even in this case, the characteristics of finished products inevitably vary.

An embodiment of the invention will be described in detail with reference to the accompanying drawings. In the description below, like reference numerals denote like components that have substantially the same functions and structures, and a duplicate explanation is given only when necessary.

### First Embodiment

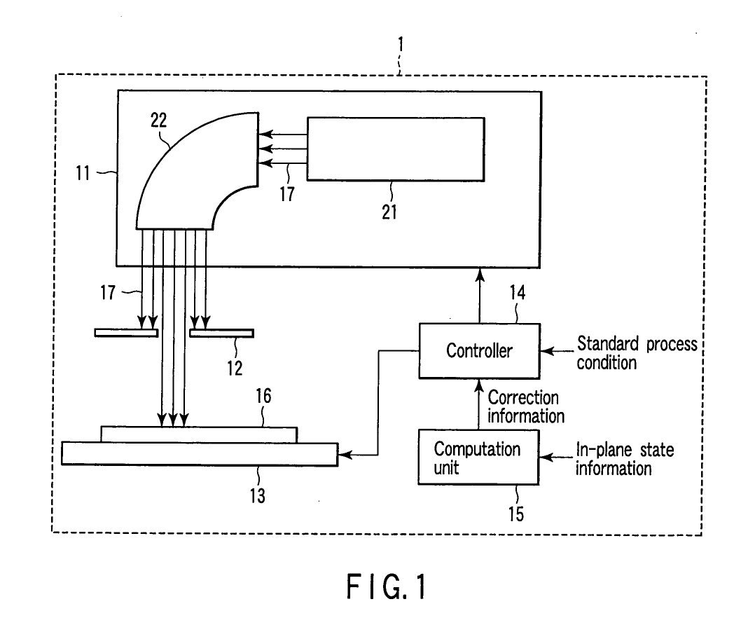

FIG. 1 is a schematic block diagram illustrating an essential part of an ion implantation apparatus 1 according to a first embodiment of the invention. As seen from FIG. 1, the ion implantation apparatus 1 comprises an ion emission unit 11, aperture slit 12, wafer stage (substrate holding unit) 13, controller 14 and computation unit 15. A to-be-processed semiconductor substrate (substrate) 16 is placed on the wafer stage 13. Although FIG. 1 shows only one to-be-processed substrate 16, a plurality of substrates 16 can be placed on the wafer stage 13.

The ion emission unit 11 emits an ion beam to the substrate 16 at a predetermined implantation angle. More specifically, the ion emission unit 11 generates an ion beam 17, diverges the beam 17 to a size that enables a predetermined region of the substrate to be processed, makes parallel the orbits of the ions that form the diverged ion beam, and directs the ion beam 17 to the to-be-processed substrate 16. The ion emission unit 11 includes, for example, an ion beam generator 21 and collimator magnet 22.

The ion beam generator 21 has an ion source, analyzer magnet, acceleration tube, electrostatic scanner, and etc., which are not shown. The analyzer magnet takes target ions out of the ions generated by the ion source. The acceleration tube accelerates the target ions to a desired speed and emits them. The electrostatic scanner diverges the emitted ion beam 17 of a certain orbit into radiation of an appropriate size radiating in all directions. The diverged ion beam 17 enters the collimator magnet 22, which converts the diverged ion beam 17 into a parallel beam and guides it to the to-be-processed substrate 16. A deflector may be further employed to adjust the orbit of the ion beam 17 guided from the collimator magnet 22, utilizing changes in electric field.

The diverged ion beam 17 emitted from the ion emission unit 11 passes through the aperture slit 12, which adjusts the spot size of the ion beam 17 to the region of the to-be-processed substrate 16 in which ions should be implanted.

The wafer stage 13 is moved by the controller 14 to a position where the region of the substrate 16 in which ions should be implanted is positioned just below the aperture slit 12.

The controller 14 controls the ion emission unit 11 and wafer stage 13 so that ions will be implanted, under predetermined conditions, into each of the regions acquired by arbitrarily dividing the to-be-processed substrate 16. Generally, the controller 14 performs control so that ions will be implanted into all regions of the substrate 16 under standard process conditions. The standard process conditions are the conditions generally set in an ion implantation process, including, for example, the dose amount (amount of emitted ions) and the acceleration speed.

Further, when the controller 14 is supplied from the computation unit 15 with correction information concerning each of the regions of the substrate 16, it prepares correcting process conditions from the standard process conditions based on the correction information. Specifically, the correcting process conditions are prepared using the standard process conditions and in-plane state information concerning each region of the substrate 16. The controller 14 controls the ion emission unit 11 and wafer stage 13 so that ions will be implanted into each region of the substrate 16 under the corresponding correcting process conditions.

The computation unit 15 is supplied with in-plane state information, described later, used for preparing correcting process conditions. The in-plane state information indicates variations in state between the regions of each substrate 16 caused in a process, such as an etching process, exposure process, deposition process, and another ion implantation process, performed before the ion implantation process. The state variations may be caused in one or more processes. The computation unit 15 prepares correction information based on in-plane state information concerning each region of each substrate 16, and supplies it to the controller 14. In FIG. 1, the controller 14 and computation unit 15 are expressed in the form of blocks that execute respective functions. Alternatively, they may be realized by a single device or programs.

The plurality of regions mean the following regions: If the process before the ion implantation process performed by the ion implantation apparatus 1 is one for processing the substrates 16 one by one (single-substrate process), the regions indicate those of each substrate 16. In this case, in-plane state information indicating each region of each substrate 16 is acquired, and correcting process conditions are prepared which enable variations in state between the regions to be reduced.

In contrast, if the process before the ion implantation process performed by the ion implantation apparatus 1 is one for simultaneously processing a plurality of the substrates 16 (batch process), the regions indicate those of all substrates 16. Further, regions may indicate the regions of different substrates 16 where variations do not occur in a single-substrate process but occur among the different substrates 16 on the same coordinates. That is, the above-mentioned “regions” indicate all regions of all substrates 16 at maximum in the specification.

The in-plane state information will now be described using some examples.

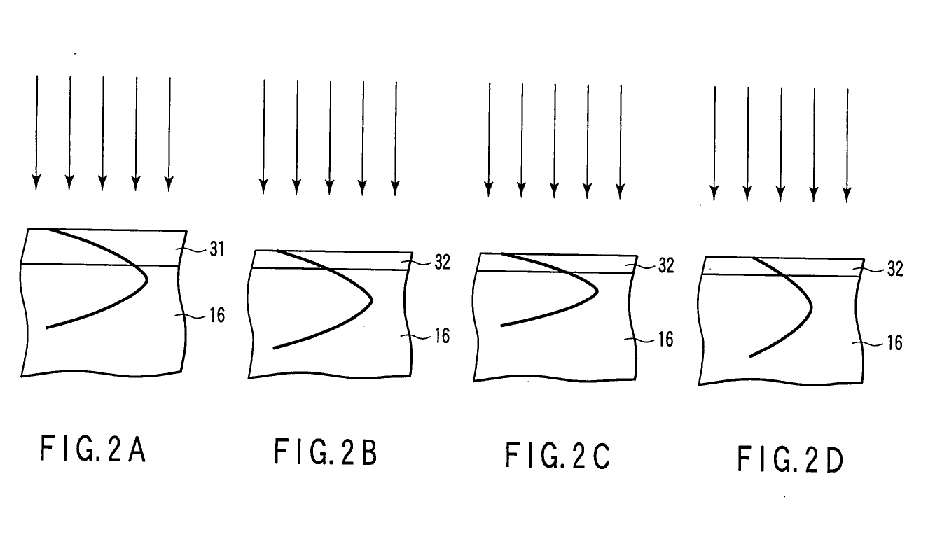

Firstly, there exist variations in film thickness caused in, for example, a deposition process. In this case, the amount of ions implanted and the acceleration speed, etc. are adjusted in accordance with the film thickness. If ions are implanted under the same conditions through films of different thicknesses, the amount of ions (impurities) implanted in the semiconductor substrate 16 or a doped layer formed above of the substrate 16 varies. More specifically, as shown in FIGS. 2A and 2B, if ions are implanted through a thin film 32, the amount of ions implanted is larger than a case where they are implanted through a thick film 31. Further, the position of the peak impurity concentration from the surface of the substrate 16 differs between the two cases. In FIGS. 2A and 2B, concerning the solid curves, the horizontal axis indicates the impurity concentration in the depth direction of the substrate 16. To suppress such variations in profiles concerning the impurity concentration, correction is performed to reduce the ion acceleration speed (see FIG. 2C), or to reduce the dose amount of ions (see FIG. 2D) in the thin film. As a result, the profiles become closer to that of FIG. 2A. Further, the acceleration speed and/or the amount of ions may be increased in the thick film.

Secondly, the in-plane state information may be variations in pattern width which occur in the exposure process and etching process. For example, when ions are implanted using a certain pattern (insulation film 33) as a mask as shown in FIGS. 3A and 3B, variations in a pattern width W contribute to variations in the area of an impurity region 34 into which ions are implanted. Accordingly, when the resistance of wiring is determined from the impurity concentration of the impurity region 34 with ions implanted therein, if ions are implanted under the same conditions, the resistance of the wiring is low where the pattern width W is wide. In contrast, the resistance is high where the pattern width W is narrow. Therefore, where the pattern width W is narrow, an amount of ions implanted (dose amount) is increased to reduce the resistance of the wiring. Otherwise, where the pattern width W is wide, an amount of ions implanted is decreased to avoid higher resistance of the wiring.

Thirdly, the in-plane state information may be an impurity concentration determined in another ion implantation process performed before the ion implantation process by the ion implantation apparatus 1. For example, there is a case where the impurity concentration may vary in different regions during the formation of a well 42 as shown in FIG. 4. In this case, the impurity concentration of a channel region 44 below a gate electrode 43 is influenced by the variations. To reduce the variations, the conditions for implanting ions into the channel region 44 to adjust the threshold voltage are corrected in units of regions in accordance with the impurity concentration of the well 42. Similar correction may be performed concerning the impurity concentrations of an extension layer 41a and source/drain layer 41b.

More specifically, if the conductivity type of the well 42 is the same as that of the ions to be implanted to the channel region 44, ions are implanted to the region having a lower impurity concentration than a desired one under higher dose amount than the standard one and to the region having a higher impurity concentration than a desired one under lower dose amount than the standard one. On the other hand, if the conductivity type of the well 42 is different from that of the ions to be implanted to the channel region 44, higher dose amount of ions are implanted to a higher impurity concentration region and lower dose amount of ions are implanted to a lower impurity concentration region.

In the ion implantation apparatus according to the first embodiment of the invention, ions are implanted into each region of a single or a plurality of the substrates 16 under correcting process conditions determined for each region. The correcting process conditions are acquired by correcting the standard process conditions used when there are no variations in state between the regions of the substrate(s) 16, based on the variations in state between the regions of the substrate(s) 16 caused before the process performed by the ion implantation apparatus of the invention. Thus, in the ion implantation process, the variations in state between the regions caused in the previous process can be corrected. As a result, semiconductor devices with a small range of characteristics variations can be mass-produced.

### Second Embodiment

In the first embodiment, correcting process conditions are determined based on the state of each region of the substrate 16 assumed immediately before the ion implantation process. In contrast, in a second embodiment, correcting process conditions are determined based on characteristics of a previously finished semiconductor device.

The ion implantation apparatus of the second embodiment has a structure similar to that of the first embodiment. In the second embodiment, characteristics of a previously finished semiconductor device, such as the transistor threshold voltage, resistance and leak current of the device, are used as in-plane state information. Accordingly, in the second embodiment, the transistor threshold voltage, resistance and leak current, etc., of each region of the substrate 16 are measured.

Variations in characteristics between finished products occur because of variations in characteristics between the results of various semiconductor-manufacturing processes. It is difficult to determine which variations should be corrected, since variations in different processes may be offset or promoted. However, it is possible to perform ion implantation under conditions suitable for each region in order to reduce the actually occurred variations in characteristics between finished products, regardless of their causes. To this end, ion implantation is performed under different conditions between regions, based on the characteristics of the products previously finished by the same processes as employed at the present stage.

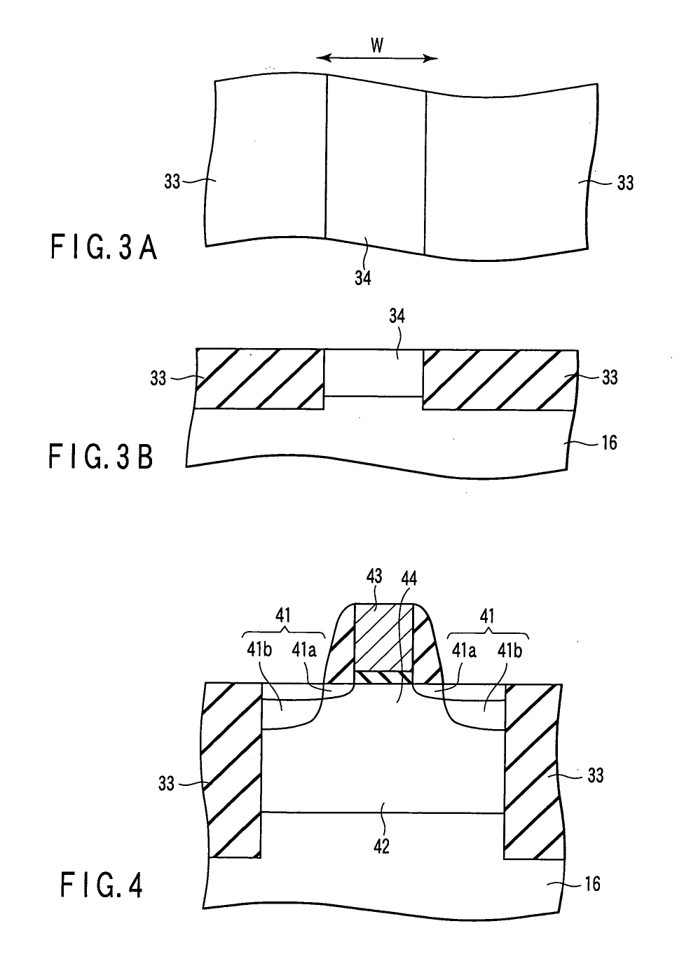

A description will now be given of a specific example in which ion implantation into a channel region was performed under different conditions between regions to correct variations in the threshold voltage of a transistor between the regions. FIG. 5 shows, as examples, the transistor threshold voltages of pre-acquired finished products corresponding to respective regions. More specifically, FIG. 5 shows an example in which 31 chips are formed on each of the six substrates. As can be understood from FIG. 5, variations in threshold voltage occur between the chips of the same positions, depending upon the substrates 16, and variations in threshold voltage also occur between different chips (regions) on each substrate 16. The threshold voltage information shown in FIG. 5 is input to the computation unit 15.

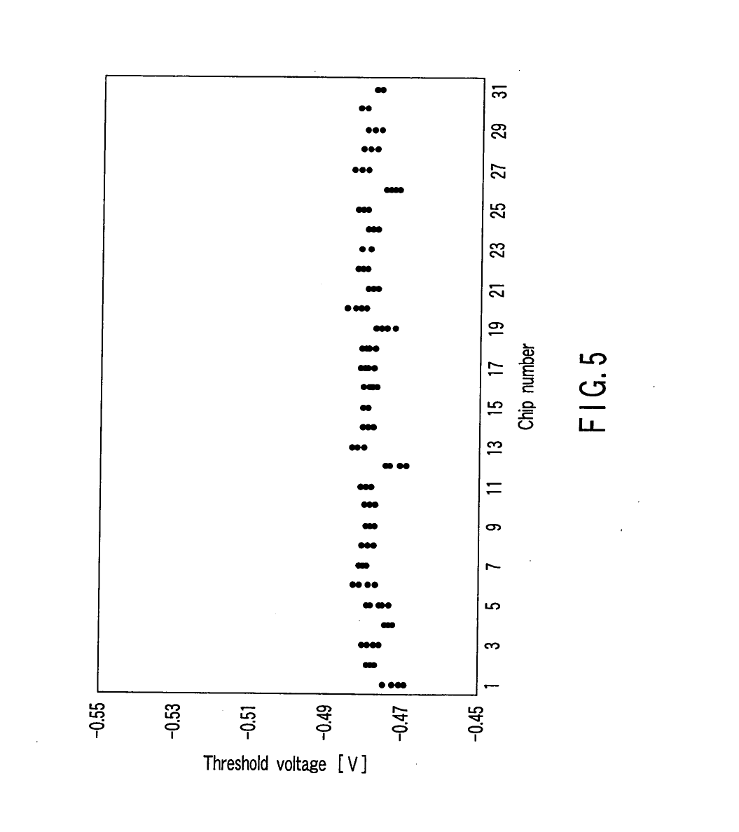

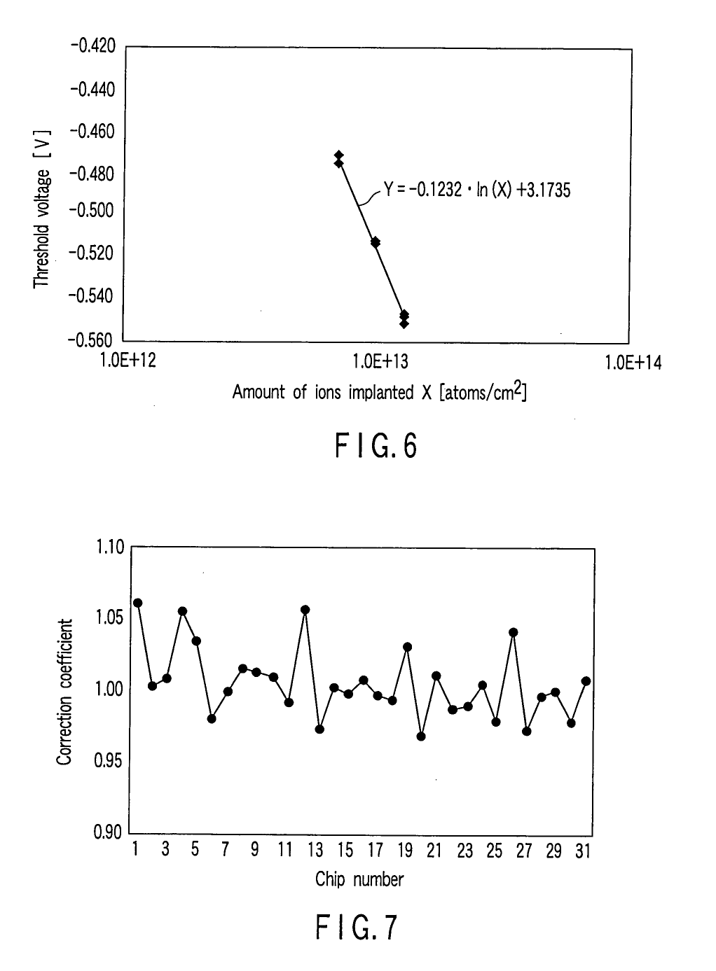

FIG. 6 shows, as an example, the change ratio of the threshold voltage to the amount of implanted ions. The change ratio is beforehand input to the computation unit 15. Using the change ratio and threshold voltage information, the computation unit 15 computes a correction coefficient for each chip with respect to a standard process condition (standard ion implantation condition) in order to reduce variations in threshold voltage between chips. FIG. 7 shows, as examples, the thus-obtained correction coefficients. As shown in FIG. 7, a correction coefficient exceeding a correction coefficient of 1 (no correction is performed, i.e., the standard process condition is utilized) is imparted to chips having lower threshold voltages, while a correction coefficient lower than the correction coefficient of 1 is imparted to chips having higher threshold voltages. FIG. 7 shows the computation results acquired using the average threshold voltage of each chip in FIG. 5.

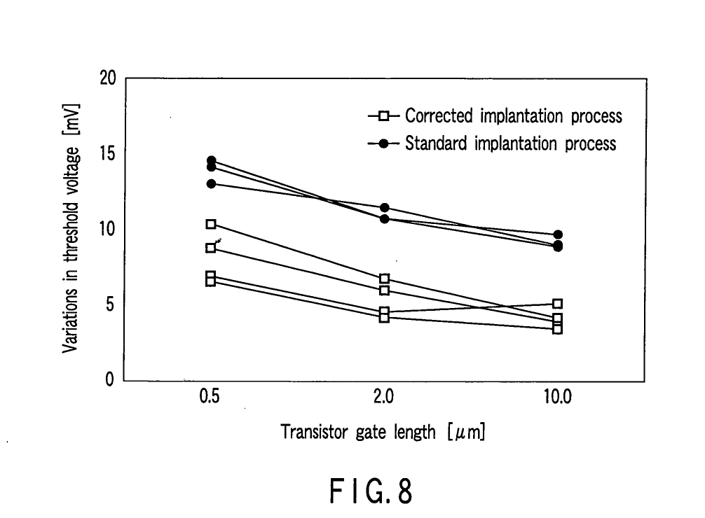

The controller 14 controls ion implantation so that an amount of ions, acquired by multiplying the standard process condition by a correction coefficient, is implanted into each region (each chip). FIG. 8 shows variations in threshold voltage between transistors having formed in the corrected ion implantation process as described above, and variations in threshold voltage between transistors having formed in a standard ion implantation process using the same condition. Specifically, in the standard ion implantation process using the same condition, variations in threshold voltage between transistors of different gate lengths formed on three substrates were acquired. Further, in the corrected ion implantation process employed in the second embodiment, variations in threshold voltage between transistors of different gate lengths formed on four substrates were acquired. As is evident from FIG. 8, in the standard ion implantation process, variations (the difference between the maximum and minimum values) in threshold voltage between 31 chips on each of the three substrates fall within a high range of 10 to 15 mV. In contrast, in the corrected ion implantation process, variations in threshold voltage between 31 chips on each of the four substrates fall within a low range of 10 mV or less, and the average of the variations is reduced to about ½ that of the standard implantation process.

As described above, in the ion implantation apparatus of the second embodiment, ions are implanted into the regions of a single or a plurality of substrates 16 under respective correcting process conditions prepared for the regions. The correcting process condition is prepared based on variations in characteristics between previously produced semiconductor devices. The characteristics variations between the finished products are determined from those between the regions caused in a single or a plurality of processes of the semiconductor manufacture. Therefore, it may be difficult to determine which process variations are the cause of the variations to be finally corrected. In the second embodiment, however, the characteristics variations between finished products are beforehand measured, and a correcting implantation process is performed where the measured characteristics variations can be directly corrected. This means that the characteristics variations can easily be corrected, which enables mass production of semiconductor devices with a small range of characteristics variations.

The second embodiment can be combined with the first embodiment. In this case, in, for example, a first manufacturing process of semiconductor devices, variations in state between the regions of a substrate caused before the ion implantation process using the ion implantation apparatus 1 are corrected as in the first embodiment. After that, information concerning the characteristics of semiconductor devices finished in the process (or processes) after the first-mentioned one is acquired. This information is utilized to perform ion implantation for production of semiconductor devices in a second manufacturing process. Information concerning the finished products is acquired from the second manufacturing process and used in a third manufacturing process. The sequence of processes is repeated to reduce characteristics variations between semiconductor devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An ion implantation apparatus comprising:
an ion emission unit configured to emit ions to a plurality of regions of at least one substrate under different conditions;
a substrate holding unit configured to hold the substrate and change a position of the at least one substrate relative to the ions emitted from the ion emission unit;
a computation unit configured to prepare a correcting process condition for each of the regions based on correction information beforehand input for each of the regions, the correcting process condition being acquired by correcting a standard process condition used for ion emission; and
a controller which controls the ion emission unit and the substrate holding unit to emit the ions to each of the regions under the correcting process condition.

2. The apparatus according to claim 1, wherein the correction information is based on a state of each of the regions of the at least one substrate assumed before the ions are emitted.

3. The apparatus according to claim 1, wherein the correction information is based on characteristics of semiconductor devices pre-formed in regions of at least one substrate using the ion implantation apparatus.

4. The apparatus according to claim 1, wherein the regions are different regions of a single substrate.

5. The apparatus according to claim 1, wherein the regions are regions at a same location of each of a plurality of substrates.

6. The apparatus according to claim 1, wherein
the ion emission unit emits ions under the correcting process condition to the substrate through a film formed on the substrate, and
the correcting process condition includes acceleration speed or dose amount set according to difference between a thickness of the film and a desired thickness.

7. The apparatus according to claim 1, wherein
the ion emission unit emits ions under the correcting process condition to the substrate through a film formed on the substrate,
ions are emitted through the film having a desired thickness under the standard process condition, and
the correcting process condition includes lower acceleration speed or dose amount, under which ions are emitted through the film thinner than a desired thickness, than the standard process condition or higher acceleration speed or dose amount, under which ions are emitted through the film thicker than a desired thickness, than the standard process condition.

8. The apparatus according to claim 1, wherein
the ion emission unit emits ions under the correcting process condition to a region, which is defined by a film formed on the substrate, of the substrate, and
the correcting process condition includes dose amount set according to difference between a size of the region and a desired size.

9. The apparatus according to claim 1, wherein
the ion emission unit emits ions to a region, which is defined by a film formed on the substrate, of the substrate,
ions are emitted to the region having a desired size under the standard process condition, and
the correcting process condition includes higher dose amount, under which ions are emitted to the region smaller than a desired size, than the standard process condition or lower dose amount, under which ions are emitted to the region larger than a desired size, than the standard process condition.

10. The apparatus according to claim 1, wherein
the ion emission unit emits ions under the correcting process condition to a region, to which impurities are previously implanted, of the substrate, and
the correcting process condition includes dose amount set according to a relationship between a conductivity type of the region and that of the ions and a difference between a concentration of the impurities of the region and a desired concentration of the impurities.

11. The apparatus according to claim 1, wherein
the ion emission unit emits ions to a region, to which impurities of a same conductivity type as that of the ions are previously implanted, of the substrate,
ions are emitted to the region having a desired concentration of the impurities under the standard process condition, and
the correcting process condition includes higher dose amount, under which ions are emitted to the region having a lower concentration of the impurities than a desired concentration of the impurities, than the standard process condition or lower dose amount, under which ions are emitted to the region having a higher concentration of the impurities than a desired concentration of the impurities, than the standard process condition.

12. An ion implantation method for use in an ion implantation apparatus capable of emitting ions to a plurality of regions of at least one substrate under different conditions, comprising:
preparing a correcting process condition for each of the regions based on correction information beforehand input for each of the regions, the correcting process condition being acquired by correcting a standard process condition used for ion emission; and
emitting the ions to each of the regions under the correcting process condition.

13. The method according to claim 12, wherein the preparing the correcting process condition includes:
inputting state information indicating a state of each of the regions of the at least one substrate assumed before the ions are emitted; and
correcting the standard process condition based on the state information.

14. The method according to claim 12, wherein the preparing the correcting condition includes:
inputting state information indicating characteristics of semiconductor devices pre-formed in regions of at least one substrate using the ion implantation apparatus; and
correcting the standard process condition based on the state information.

15. The method according to claim 12, wherein the regions are different regions of a single substrate, and the emitting the ions includes emitting the ions to the single substrate.

16. The method according to claim 12, wherein the regions are regions at a same location of each of a plurality of substrates, and the emitting the ions includes emitting the ions to the plurality of substrates.

17. The method according to claim 12, wherein emitting the ions includes emitting ions to the substrate through a film, which is formed on the substrate, under acceleration speed or dose amount set according to a difference between a thickness of the film and a desired thickness.

18. The method according to claim 12, wherein emitting the ions includes emitting ions to a region of the substrate, which is defined by a film formed on the substrate, under dose amount set according to a difference between a size of the region and a desired size.

19. The method according to claim 12, wherein emitting the ions includes emitting ions to a region, to which impurities are previously implanted, under dose amount set according to a relationship between a conductivity type of the region and that of the ions and a difference between a concentration of the impurities in the region and a desired concentration of the impurities.
